(19) United States
(12) Patent Application Publication
(10) Pub. No.: US 2025/0267963 A1
(43) Pub. Date: Aug. 21, 2025

(54) PHOTOELECTRIC CONVERSION APPARATUS AND DEVICE

(71) Applicant: CANON KABUSHIKI KAISHA, Tokyo (JP)

(72) Inventor: DAIKI SHIRAHIGE, Kanagawa (JP)

(21) Appl. No.: 19/043,186

(22) Filed: Jan. 31, 2025

(30) Foreign Application Priority Data
Feb. 16, 2024 (JP) 2024-021762

(51) Int. Cl. H10F 39/00; H10F 39/18

(52) U.S. Cl. CPC H10F 39/8027; H10F 39/182; H10F 39/8053; H10F 39/8063; H10F 39/807

(57) ABSTRACT

A photoelectric conversion apparatus includes pixels arranged in an array, wherein the pixels each include a microlens, first to fourth photoelectric conversion elements on a substrate in two rows and two columns, first to fourth isolation portions, the first and third isolation portions and a first opening are aligned in a first direction, the second and fourth isolation portions and a second opening are aligned in a second direction, the first opening extends from the first surface to the second surface, the pixels include first and second pixels, the first pixel being closer to a center of an array of the pixels than the second pixel, arrangement of the first opening in the first pixel is different from that in the second pixel, the pixels are each surrounded by an inter-pixel isolation portion, and the first to fourth isolation portions are in contact with the inter-pixel isolation portion.

### BACKGROUND

### Technical Field

The aspect of the embodiments relates to a photoelectric conversion apparatus and a device.

### Description of the Related Art

A photoelectric conversion apparatus is known in which a plurality of pixels including a plurality of photoelectric conversion elements and a floating diffusion portion shared by the plurality of photoelectric conversion elements is arranged side by side. For example, according to United States Patent Application Publication No. 2016/0056200, it is discussed that one pixel includes four photoelectric conversion elements arranged in two rows and two columns and a floating diffusion portion arranged among the four photoelectric conversion elements, and an isolation portion having a trench structure is arranged between the photoelectric conversion elements in the pixel.

In a case where pixels in a pixel array are uniformly formed, there is a possibility that sensitivity may decrease in a pixel where light is not easily focused on the center of the pixel, such as a pixel arranged at an edge portion of the pixel array.

### SUMMARY

According to an aspect of the embodiments, a photoelectric conversion apparatus in which a plurality of pixels is arranged in an array, wherein each of the plurality of pixels includes a microlens, a first photoelectric conversion element, a second photoelectric conversion element, a third photoelectric conversion element, and a fourth photoelectric conversion element that are provided on a substrate having a first surface and a second surface facing the first surface and are arranged in two rows and two columns to receive light via the microlens, a first isolation portion provided between the first photoelectric conversion element and the second photoelectric conversion element, a second isolation portion provided between the first photoelectric conversion element and the third photoelectric conversion element, a third isolation portion provided between the third photoelectric conversion element and the fourth photoelectric conversion element, and a fourth isolation portion provided between the second photoelectric conversion element and the fourth photoelectric conversion element, wherein the first isolation portion, the third isolation portion, and a first opening provided between the first isolation portion and the third isolation portion are aligned in a first direction, wherein the second isolation portion, the fourth isolation portion, and a second opening provided between the second isolation portion and the fourth isolation portion are aligned in a second direction, wherein the first opening extends from the first surface to the second surface, wherein the plurality of pixels includes a first pixel and a second pixel separated in the first direction, and the first pixel is closer to a center of an array formed of the plurality of pixels than the second pixel, wherein arrangement of the first opening in the first pixel is different from arrangement of the first opening in the second pixel, wherein each of the plurality of pixels is surrounded on four sides by an inter-pixel isolation portion, and wherein each of the first isolation portion, the second isolation portion, the third isolation portion, and the fourth isolation portion is in contact with the inter-pixel isolation portion.

Further features of the present invention will become apparent from the following description of exemplary embodiments with reference to the attached drawings.

### BRIEF DESCRIPTION OF THE DRAWINGS

FIG. 1 is a block diagram illustrating a photoelectric conversion apparatus according to an exemplary embodiment.

FIGS. 2A, 2B, and 2C are schematic diagrams of a pixel according to the exemplary embodiment.

FIGS. 3A, 3B, 3C, 3D, 3E, 3F, 3G, 3H, 3I, and 3J are schematic diagrams of a pixel according to a first exemplary embodiment.

FIGS. 4A, 4B, 4C, 4D, 4E, 4F, and 4G are schematic diagrams of a pixel according to a second exemplary embodiment.

FIGS. 5A, 5B, and 5C are schematic diagrams of a pixel according to a third exemplary embodiment.

FIGS. 6A, 6B, and 6C are schematic diagrams of a pixel according to a fourth exemplary embodiment.

FIGS. 7A, 7B, and 7C are schematic diagrams of a pixel according to a fifth exemplary embodiment.

FIGS. 8A, 8B, and 8C are schematic diagrams of a pixel according to the fifth exemplary embodiment.

FIGS. 9A, 9B, and 9C are schematic diagrams of a device according to a sixth exemplary embodiment.

### DESCRIPTION OF THE EMBODIMENTS

A configuration according to each exemplary embodiment is described with reference to the attached drawings. In each exemplary embodiment described below, an image capturing apparatus is mainly described as an example of a photoelectric conversion apparatus. However, a photoelectric conversion apparatus is not limited to the image capturing apparatus and can be applied to another example of the photoelectric conversion apparatus. For example, there are a ranging apparatus (an apparatus that measures a distance using focus detection or time of flight (TOF)), a light metering apparatus (an apparatus that measures an amount of incident light or the like), and the like.

Semiconductor regions, conductivity types of wells, and dopants to be implanted described in the following exemplary embodiments are merely examples and are not limited only to the conductivity types and dopants described in the exemplary embodiments. The conductivity types and dopants described in the exemplary embodiments can be appropriately changed, and potentials of the semiconductor regions and wells can be appropriately changed according to the change.

Conductivity types of transistors described in the following exemplary embodiments are merely examples and are not limited only to the conductivity types described in the exemplary embodiments. The conductivity types described in the exemplary embodiments can be appropriately changed, and potentials of gates, sources, and drains of the transistors can be appropriately changed according to the change.

For example, in a case of a transistor operated as a switch, low and high levels of the potential to be supplied to a gate may be reversed according to a change in the conductivity type with respect to the description in the exemplary embodiments. Conductivity types of semiconductor regions described in the following exemplary embodiments are also examples and are not limited only to the conductivity types described in the exemplary embodiments. The conductivity types described in the exemplary embodiments can be appropriately changed, and potentials of the semiconductor regions can be appropriately changed according to the change.

In the following exemplary embodiments, a connection between elements in a circuit may be described. In this case, even if there is another element between the elements of interest, the elements of interest are treated as being connected unless otherwise specified. For example, it is assumed that an element A is connected to one node of a capacitive element C having a plurality of nodes, and an element B is connected to another node. Even in such a case, the elements A and B are treated as being connected unless otherwise specified.

Metal members such as wires and pads described in the present specification may be made of a single metal element or a mixture (alloy). For example, a wire described as a copper wire may be made of copper alone or a material that mainly includes copper and further includes another component. For example, a pad connected to an external terminal may be made of aluminum alone or a material that mainly includes aluminum and further includes another component. The copper wire and aluminum pad described here are merely examples, and can be changed to various metals.

The wire and pad described here are one example of metal members used in a photoelectric conversion apparatus and can be applied to other metal members.

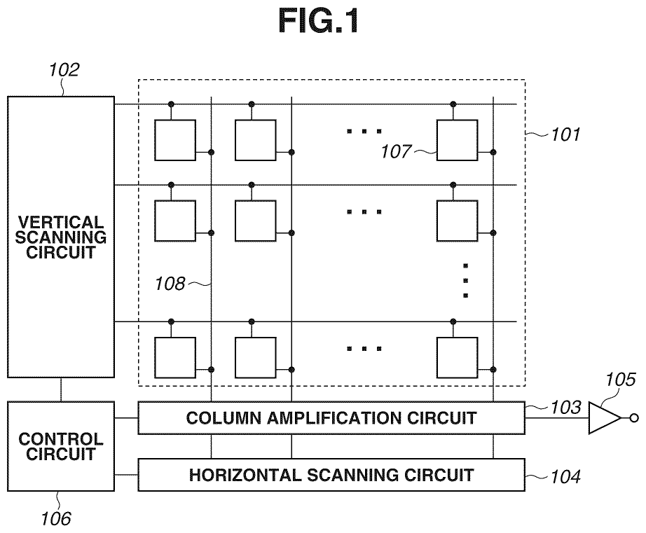

A photoelectric conversion apparatus according to a first exemplary embodiment is described with reference to FIGS. 1 to 3J.

FIG. 1 is a schematic diagram illustrating a configuration of a photoelectric conversion apparatus 100 according to the present exemplary embodiment. The photoelectric conversion apparatus 100 in FIG. 1 includes a pixel array 101, a vertical scanning circuit 102, a column amplification circuit 103, a horizontal scanning circuit 104, an output circuit 105, a control circuit 106, and a column signal line 108.

The pixel array 101 includes a plurality of pixels 107 arranged in a matrix across a plurality of rows and a plurality of columns. In each row of the pixel array 101, a control signal line is arranged extending in a row direction (a lateral direction in FIG. 1). The control signal lines are respectively connected to the pixels 107 arranged in the row direction and form signal lines common to the pixels 107. In each column of the pixel array 101, the column signal line 108 is arranged extending in a column direction (vertical direction in FIG. 1). The column signal lines 108 are respectively connected to the pixels 107 arranged in the column direction and form signal lines common to the pixels 107. Although one column signal line 108 is illustrated in FIG. 1, a plurality of column signal lines 108 may be connected according to the number of bits of an output signal.

The number of the pixels 107 included in the pixel array 101 is not particularly limited. For example, the pixel array 101 may be formed of several thousand rows and several thousand columns of the pixels 107 as in a commonly used digital camera, or may be formed of a plurality of pixels 107 arranged in a single row or a single column. Alternatively, the pixel array 101 may be formed of a single pixel 107.

The control signal line in each row is connected to the vertical scanning circuit 102. The vertical scanning circuit 102 is a circuit unit that supplies the pixel 107 via the control signal line with a control signal for driving a readout circuit in the pixel 107 in a case where a pixel signal is read out from the pixel 107.

One end of the column signal line 108 in each column is connected to the column amplification circuit 103. A pixel signal read out from the pixel 107 is input to the column amplification circuit 103 via the column signal line 108. The column amplification circuit 103 can include a memory that stores the pixel signal read out from the pixel 107.

The horizontal scanning circuit 104 is a circuit unit that supplies the column amplification circuit 103 with a control signal for sequentially transferring the pixel signal stored in the column amplification circuit 103 to the output circuit 105 for each column. The control circuit 106 is a circuit unit that supplies a control signal for controlling operations and timings of the vertical scanning circuit 102, the column amplification circuit 103, and the horizontal scanning circuit 104.

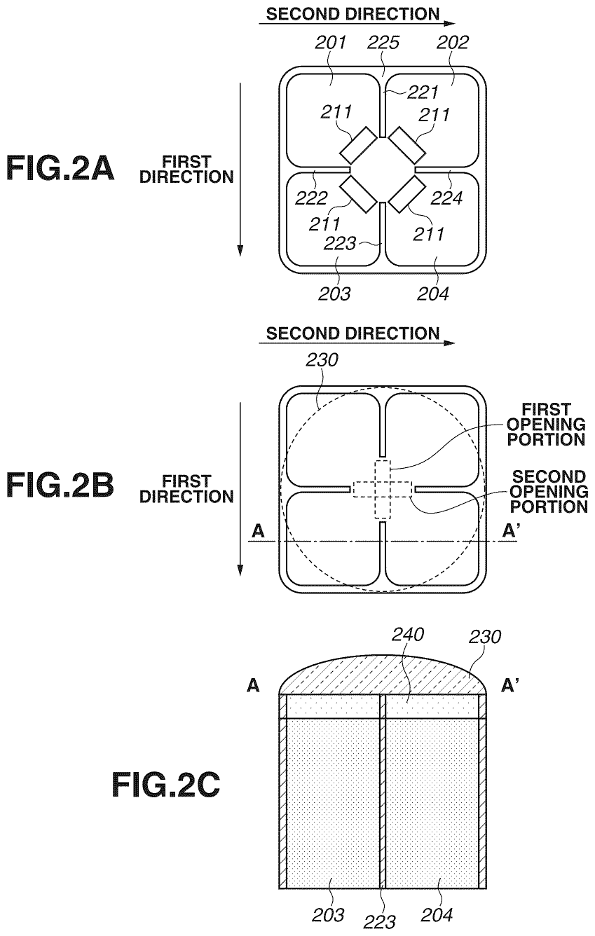

FIGS. 2A to 2C are schematic diagrams illustrating a configuration of the pixel 107. FIG. 2A is a plan view of the pixel 107 viewed from a front surface of a semiconductor substrate. FIG. 2B is a plan view of the pixel 107 viewed from a back surface of the semiconductor substrate. FIG. 2C is a cross-sectional view of the pixel 107 in an A-A′ cross section in FIG. 2B.

The pixel 107 includes four photoelectric conversion elements, a first photoelectric conversion element 201, a second photoelectric conversion element 202, a third photoelectric conversion element 203, and a fourth photoelectric conversion element 204 that are arranged in two rows and two columns. As illustrated in FIGS. 2B and 2C, one microlens 230 is provided closer to a light incident surface of the four photoelectric conversion elements, and light passing through the microlens 230 enters each photoelectric conversion element. A color filter 240 and an inner lens (not illustrated) may be further provided below the microlens 230. In FIG. 2A, each photoelectric conversion element is provided with a transfer transistor. The first photoelectric conversion element 201 includes a first transfer transistor 211, and the second photoelectric conversion element 202 includes a second transfer transistor 212. Similarly, the third photoelectric conversion element 203 includes a third transfer transistor 213, and the fourth photoelectric conversion element 204 includes a fourth transfer transistor 214. The number and positions of the transfer transistors are not limited to this example, and for example, two photoelectric conversion elements may share one transfer transistor.

Four sides of an outer periphery of the pixel 107 are surrounded by an inter-pixel isolation portion 225 that separates adjacent pixels 107 from each other. An isolation portion is provided between the photoelectric conversion elements. A first isolation portion 221 is provided between the first photoelectric conversion element 201 and the second photoelectric conversion element 202. A second isolation portion 222 is provided between the first photoelectric conversion element 201 and the third photoelectric conversion element 203. A third isolation portion 223 is provided between the third photoelectric conversion element 203 and the fourth photoelectric conversion element 204. A fourth isolation portion 224 is provided between the second photoelectric conversion element 202 and the fourth photoelectric conversion element 204. Each of the first isolation portion 221, the second isolation portion 222, the third isolation portion 223, and the fourth isolation portion 224 is provided perpendicular to at least one of the four sides of the inter-pixel isolation portion 225 in a plan view. In the present description, each isolation portion and the inter-pixel isolation portion 225 are formed in contact with each other or as an integrated body. As long as each isolation portion is provided to intersect with each side of the inter-pixel isolation portion 225, it is not essential that the isolation portion and each side of the inter-pixel isolation portion 225 are in contact with each other.

A first opening portion is formed between the first isolation portion 221 and the third isolation portion 223, and a second opening portion is formed between the second isolation portion 222 and the fourth isolation portion 224. The first isolation portion 221, the third isolation portion 223, and the first opening portion are aligned in a first direction, and the second isolation portion 222, the fourth isolation portion 224, and the second opening portion are aligned in a second direction.

Each of the inter-pixel isolation portion 225, the first isolation portion 221, the second isolation portion 222, the third isolation portion 223, and the fourth isolation portion 224 is, for example, deep trench isolation (DTI). An area where the DTI is formed has no sensitivity to light. Thus, if light passing through the microlens 230 is focused on the DTI, efficiency of a charge amount generated relative to an incident light amount is reduced, which may result in a decrease in sensitivity. As illustrated in FIG. 2B, portions (opening portions) where the DTI is not formed are provided between the first isolation portion 221 and the third isolation portion 223 and between the second isolation portion 222 and the fourth isolation portion 224. Accordingly, the decrease in sensitivity can be prevented compared with a case where the first isolation portion 221 is connected to the third isolation portion 223 and the second isolation portion 222 is connected to the fourth isolation portion 224.

In a case where an image is formed by a lens and captured at the center and periphery portions of a sensor in which pixels are arranged in an array, light is focused at the center of the pixel in the center portion (pixel in an area with a low image height), but light is not focused at the center of the pixel in the periphery portion (pixel in an area with a high image height), and a light amount entering the DTI increases. Thus, the decrease in sensitivity at the periphery portion of the sensor becomes an issue. Thus, the decrease in sensitivity can be eliminated or reduced by suitably arranging the DTI and the opening portion according to an image height. An appropriate arrangement of the opening portions according to the image height of the pixel 107 in the pixel array 101 is specifically described.

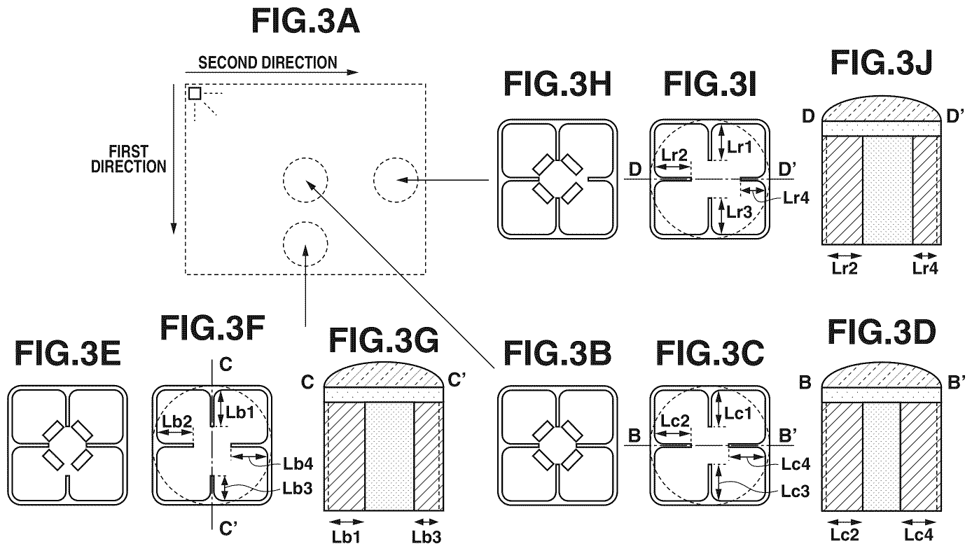

FIG. 3A is a schematic diagram of the pixel array 101. A pixel arranged near the center of the pixel array 101 is defined as a first pixel, a pixel away from the first pixel in the first direction is defined as a second pixel, and a pixel away from the first pixel in the second direction is defined as a third pixel. FIG. 3B is a plan view of a front surface of the first pixel. FIG. 3C is a plan view of a back surface of the first pixel. FIG. 3D is a cross-sectional view of the first pixel in a B-B′ cross section. FIG. 3E is a plan view of a front surface of the second pixel. FIG. 3F is a plan view of a back surface of the second pixel. FIG. 3G is a cross-sectional view of the second pixel in a C-C′ cross section. FIG. 3H is a plan view of a front surface of the third pixel. FIG. 3I is a plan view of a back surface of the third pixel. FIG. 3J is a cross-sectional view of the third pixel in a D-D′ cross section.

In the first pixel, if a length from the inter-pixel isolation portion 225 to the first isolation portion is Lc1, the second isolation portion has a length Lc2, the third isolation portion has a length Lc3, and the fourth isolation portion has a length Lc4, the length Lc1 and the length Lc3 are equal, and the length Lc2 and the length Lc4 are also equal. In FIG. 3A, Lc1=Lc2=Lc3=Lc4, and areas of the four photoelectric conversion elements, the first photoelectric conversion element 201, the second photoelectric conversion element 202, the third photoelectric conversion element 203, and the fourth photoelectric conversion element 204, are equal.

In the second pixel, if a length from the inter-pixel isolation portion 225 to the first isolation portion is Lb1, the second isolation portion has a length Lb2, the third isolation portion has a length Lb3, and the fourth isolation portion has a length Lb4, the length Lb2 and the length Lb4 are equal, and the length Lb3 is shorter than the length Lb1. In other words, the first opening portion extends in the first direction. It can also be said that the first opening portion is shifted in an outer periphery direction of the pixel array.

In the third pixel, if a length from the inter-pixel isolation portion 225 to the first isolation portion is Lr1, the second isolation portion has a length Lr2, the third isolation portion has a length Lr3, and the fourth isolation portion has a length Lr4, the length Lr1 and the length Lr3 are equal, and the length Lr4 is shorter than the length Lr2. In other words, the second opening portion extends in the second direction. It can also be said that the second opening portion is shifted in the outer periphery direction of the pixel array.

In this configuration, for example, if the first pixel and the second pixel are compared, the length of the second opening portion of the second pixel in the second direction is equal to the length of the second opening portion of the first pixel in the second direction. On the other hand, an area of the first opening portion is increased by an amount corresponding to the length Lb3 is shorter than the length Lc3.

The second pixel is the pixel 107 that is arranged at a position shifted downward from the center portion of the pixel array 101, but in the pixel arranged at such a position, a focus position of the microlens 230 may shift downward from the center of the pixel, which may result in the decrease in sensitivity. According to the present exemplary embodiment, the first opening portion extends downward, so that an area having sensitivity to incident light where the isolation portion cannot be provided extends downward. Accordingly, it is possible to suitably perform photoelectric conversion on the light passing through the microlens 230, and the decrease in sensitivity can be eliminated or reduced.

Similarly, the third pixel is the pixel 107 that is arranged at a position shifted to the right from the center portion of the pixel array 101, but in the pixel arranged at such a position, the focus position of the microlens 230 may shift to the right from the center of the pixel, which may result in the decrease in sensitivity. According to the present exemplary embodiment, the second opening portion extends to the right, so that the area having sensitivity to incident light where the isolation portion cannot be provided extends to the right. Accordingly, it is possible to suitably perform photoelectric conversion on the light passing through the microlens 230, and the decrease in sensitivity can be eliminated or reduced.

The focus position in each pixel changes in a gradational manner according to the arrangement of the pixels 107 in the pixel array 101, in one embodiment, the arrangement of the isolation portion is changed in each pixel in a gradational manner as well. However, the arrangement of the isolation portion is not limited to the change in the exact gradational manner.

For example, the pixel array 101 may be divided into three in each of the first and second directions, resulting in nine blocks, and a shift direction and a shift amount of the opening portion may be set for each block. The pixel array 101 may be divided into two blocks, a central block and a peripheral block surrounding the central block, and, in one embodiment, only the opening portion of the pixel 107 in the peripheral block may be shifted.

In this way, the position of the isolation portion inside the pixel is varied depending on the image height, and thus it is possible to suppress the decrease in sensitivity due to light being incident on the isolation portion in a high image height area.

According to the first exemplary embodiment, the arrangement of the opening portions is changed by making some isolation portions shorter than the other isolation portions. In a photoelectric conversion apparatus according to a second exemplary embodiment, an isolation portion facing a short isolation portion is longer than the other isolation portions, so that a more suitable arrangement of the isolation portions and opening portions is realized.

Description common to the first exemplary embodiment is omitted.

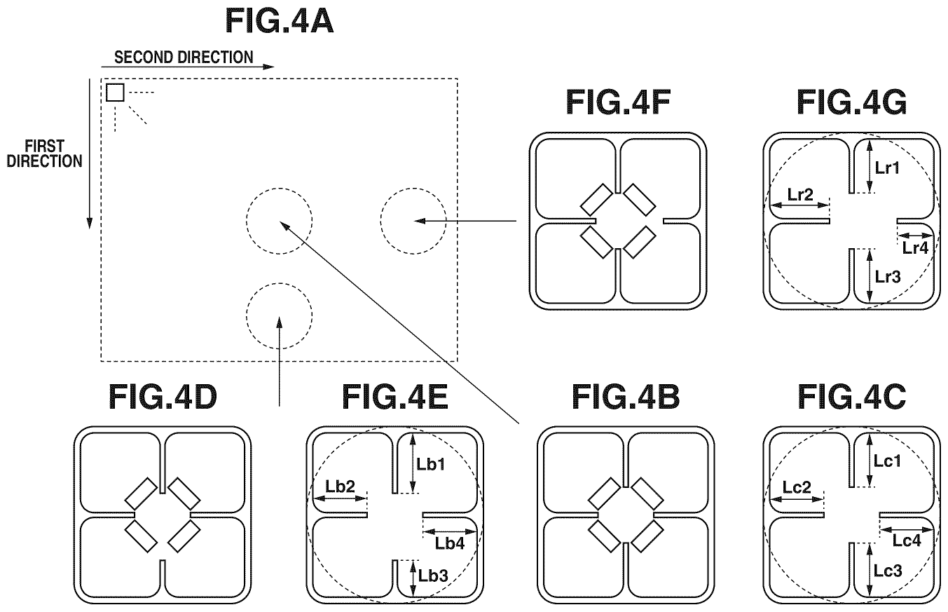

FIG. 4A is a schematic diagram of the pixel array 101. FIG. 4B is a plan view of a front surface of the first pixel. FIG. 4C is a plan view of a back surface of the first pixel. FIG. 4D is a plan view of a front surface of the second pixel. FIG. 4E is a plan view of a back surface of the second pixel. FIG. 4F is a plan view of a front surface of the third pixel. FIG. 4G is a plan view of a back surface of the third pixel.

As illustrated in FIG. 4C, the arrangement of the isolation portions and the opening portions of the first pixel is the same as that according to the first exemplary embodiment.

As illustrated in FIG. 4E, in the second pixel, the length Lb2 and the length Lb4 are equal, and the length Lb3 is shorter than the length Lb1. The length Lb1 is longer than the length Lb2 and the length Lb4, and the length Lb3 is shorter than the length Lb2 and the length Lb4. The length Lb1 is longer than the length Lc1, and the length Lb3 is shorter than the length Lc3. In FIGS. 4C and 4E, the length Lc1 and the length Lc3 are equal, and a difference between the length Lb1 and the length Lc1 is greater than a difference between the length Lb3 and the length Lc3. In other words, the length of the first opening portion of the second pixel in the first direction is greater than the length of the first opening portion of the first pixel in the first direction, in order to prevent interference with a floating diffusion portion, which is formed in the center of the pixel and to which a charge generated in the photoelectric conversion apparatus is transferred by the transfer transistor.

As illustrated in FIG. 4G, in the third pixel, the length Lr1 and the length Lr3 are equal, and the length Lr4 is shorter than the length Lr2. The length Lr2 is longer than the length Lr1 and the length Lr3, and the length Lr4 is shorter than the length Lr1 and the length Lr3. In FIGS. 4C and 4G, the length Lr2 is longer than the length Lc2, and the length Lr4 is shorter than the length Lc4. The length Lc1 and the length Lc3 are equal, and a difference between the length Lr4 and the length Lc4 is greater than a difference between the length Lr2 and the length Lc2. In other words, the length of the second opening portion of the third pixel in the second direction is greater than the length of the second opening portion of the first pixel in the second direction.

In this way, the isolation portion facing the short isolation portion is made longer than the other isolation portions, so that a decrease in saturation capacitance caused by a decrease in positive-to-negative (PN) junction capacitance due to a decrease in a total area of the isolation portions is suppressed, and an effect on pixel performance can be reduced.

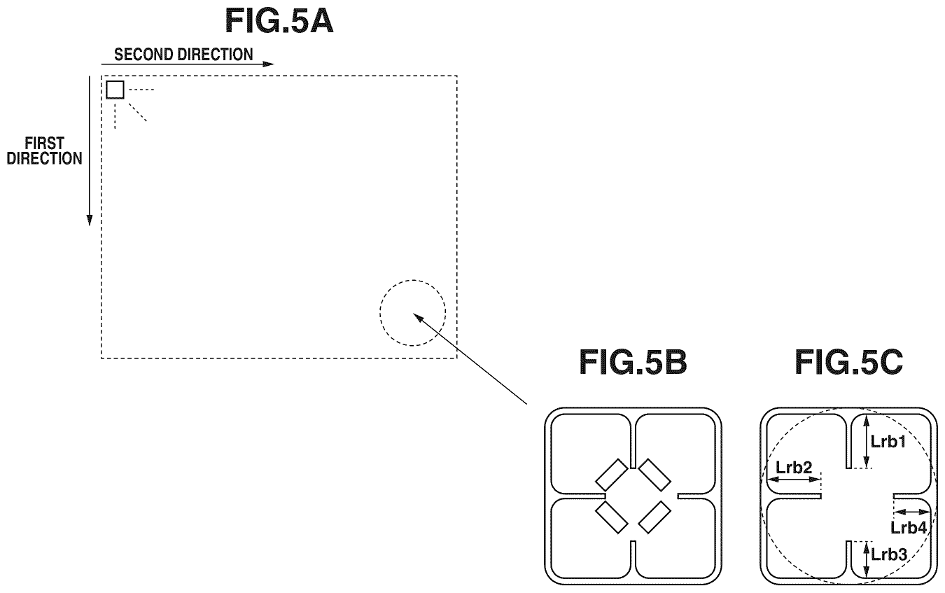

A third exemplary embodiment is described. Arrangement of isolation portions in a fourth pixel provided at a diagonal corner in the pixel array 101 is described with reference to FIGS. 5A to 5C. FIG. 5A is a schematic drawing of the pixel array 101. FIG. 5B is a plan view of a front surface of the fourth pixel. FIG. 5C is a plan view of a back surface of the fourth pixel.

As illustrated in FIG. 5C, in the fourth pixel, a length Lrb3 is shorter than a length Lrb1, and a length Lrb4 is shorter than a length Lrb2. In other words, a length of the first opening portion of the fourth pixel in the first direction is greater than a first length of the first opening portion of the first pixel, and a length of the second opening portion of the fourth pixel in the second direction is longer than the length of the second pixel of the first pixel in the second direction. In FIG. 5C, the length Lrb1 and the length Lrb2 are equal, and the length Lrb3 and the length Lrb4 are also equal, but for example, the isolation portions may be arranged so that the length Lrb4 is shorter than the length Lrb3.

FIGS. 5A to 5C illustrate the pixel 107 located at the lower right of the pixel array 101, but in the pixel arranged at such a position, the focus position of the microlens 230 may shift from the center of the pixel to the lower right, which may result in the decrease in sensitivity. According to the present exemplary embodiment, the first opening portion extends downward, and the second opening portion extends to the right, so that an area having sensitivity where the isolation portion cannot be provided extends to the lower right. Accordingly, it is possible to suitably perform photoelectric conversion on the light passing through the microlens 230, and the decrease in sensitivity can be suppressed.

The exemplary embodiments of the present invention are not limited to a case where the arrangement of the opening portions is changed by making the lengths of the two isolation portions facing each other in the first direction or the second direction different from each other. The decrease in sensitivity can be prevented even in the pixel 107 that is arranged in the diagonal corner in the pixel array 101 by optimizing the arrangement of the opening portions by changing the lengths of the isolation portion arranged extending in the first direction and the isolation portion arranged extending in the second direction.

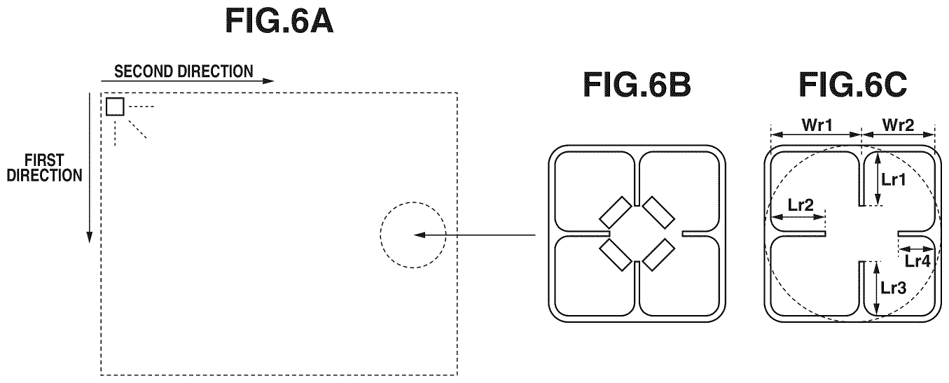

In the photoelectric conversion apparatuses described according to the first to third exemplary embodiments, a size of the opening portion is varied depending on a position at which the pixel is arranged in the pixel array 101, but a position at which the isolation portion in the pixel is in contact with the inter-pixel isolation portion is constant for each pixel. In contrast, according to a fourth exemplary embodiment described with reference to FIGS. 6A to 6C, a position at which each isolation portion is in contact with an inter-pixel isolation portion is also changed depending on a position at which a pixel is arranged and an image height, so that a pixel configuration that is more suitable for suppressing a decrease in sensitivity is realized.

FIG. 6A is a schematic drawing of the pixel array 101. FIG. 6B is a plan view of a front surface of the second pixel. FIG. 6C is a plan view of a back surface of the second pixel. In the pixel 107 illustrated in FIGS. 6A to 6C, the length Lr1 and the length Lr3 are equal, and the length Lr2 is greater than the length Lr4. If compared with the first pixel, the center of the second opening portion is shifted toward the fourth isolation portion (to the right in the drawing), and accordingly, positions at which the first isolation portion and the third isolation portion are in contact with the inter-pixel isolation portion 225 surrounding the four photoelectric conversion elements are shifted toward the fourth isolation portion. Accordingly, a lateral width Wr1 of the first photoelectric conversion element and the third photoelectric conversion element is greater than a lateral width Wr2 of the second photoelectric conversion element and the fourth photoelectric conversion element. In other words, in this arrangement, an area of the first photoelectric conversion element and the third photoelectric conversion element is greater than an area of the second photoelectric conversion element and the fourth photoelectric conversion element.

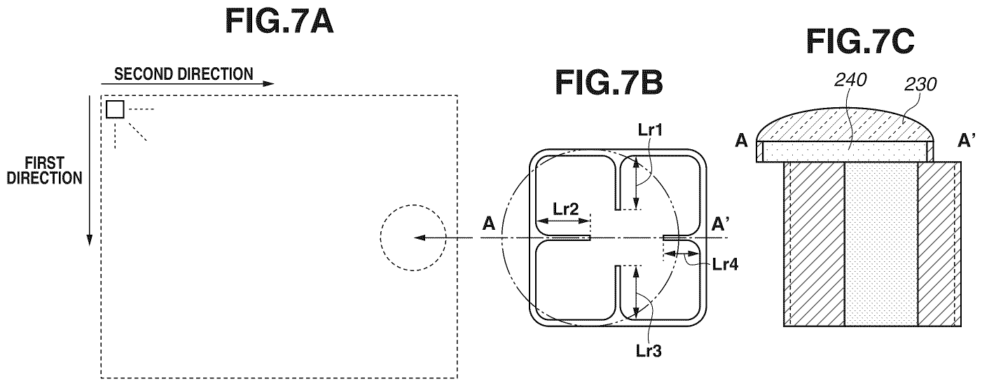

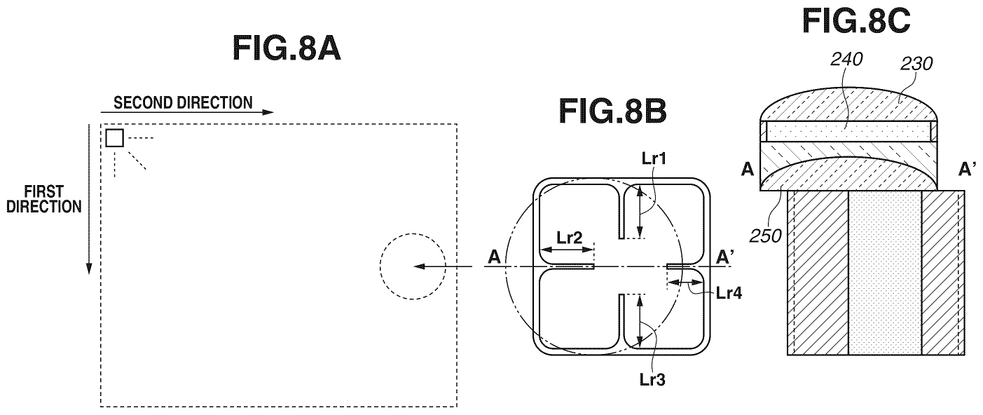

A photoelectric conversion apparatus according to a fifth exemplary embodiment is described with reference to FIGS. 7A to 7C, and 8A to 8C. In the photoelectric conversion apparatus illustrated in FIGS. 7A to 7C, positions of the microlens 230, the color filter 240, and a color filter grid are changed according to an image height in addition to the change in the isolation portions described according to the first to fourth exemplary embodiments. The photoelectric conversion apparatus illustrated in FIGS. 8A to 8C further includes an inner lens 250, and a position of the inner lens 250 is also changed according to the image height. FIG. 7A is a schematic drawing of the pixel array 101. FIG. 7B is a plan view of a back surface of the second pixel. FIG. 7C is a cross-sectional view of the second pixel in an A-A′ cross section in FIG. 7B. Similarly, FIG. 8A is a schematic drawing of the pixel array 101, and FIG. 8B is a plan view of a back surface of the second pixel. FIG. 8C is a cross-sectional view of the second pixel in an A-A′ cross section in FIG. 8B.

In other words, a distance between the center of the microlens 230 in the second pixel and the center of the second pixel in the first direction is greater than a distance between the center of the microlens 230 in the first pixel in the center of the pixel array 101 and the center of the first pixel in the first direction. Similarly, a distance between the center of the inner lens 250 in the second pixel and the center of the second pixel in the first direction is greater than a distance between the center of the inner lens 250 in the first pixel in the center of the pixel array 101 and the center of the first pixel in the first direction. A distance between the center of the color filter 240 in the second pixel and the center of the second pixel in the first direction is greater than a distance between the center of the color filter in the first pixel and the center of the first pixel in the first direction.

Accordingly, it is possible to prevent the decrease in sensitivity in the pixel in the periphery portion of the pixel array 101. By shifting the color filter, oblique incident light can be photoelectrically converted at an appropriate pixel even at the edge portion of the pixel array 101, and color accuracy can be ensured.

In FIG. 8C, the microlens 230, the color filter 240, and the inner lens 250 are configured so that their shift amounts from the center of the pixel are equal to each other, but the configuration is not limited to this example. For example, the microlens 230 may be shifted the most from the center of the pixel, and the color filter 240 may be shifted from the center of the pixel by an average amount of the shift amount of the inner lens 250 and the shift amount of the microlens 230.

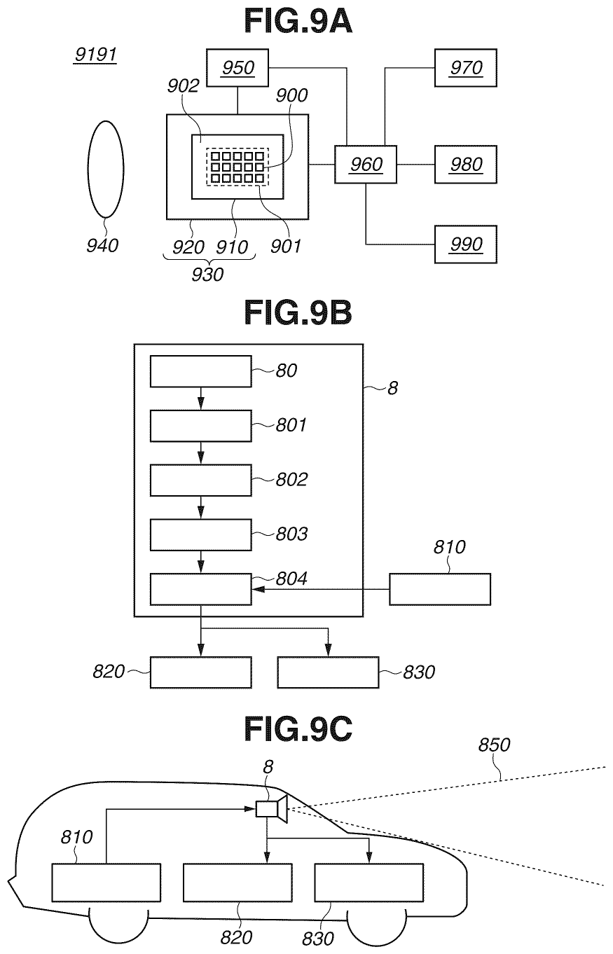

A sixth exemplary embodiment can be applied to any of the first to fifth exemplary embodiments. FIG. 9A is a schematic diagram illustrating a device 9191 including a semiconductor apparatus 930 according to the present exemplary embodiment. The photoelectric conversion apparatus according to any of the above-described exemplary embodiments can be applied to the semiconductor apparatus 930. The device 9191 including the semiconductor apparatus 930 is described in detail. The semiconductor apparatus 930 can include a semiconductor device 910 as well as a package 920 that accommodates the semiconductor device 910. The package 920 can include a base member to which the semiconductor device 910 is fixed and a lid member such as glass facing the semiconductor device 910. The package 920 may further include bonding members such as a bonding wire and a bump that connect a terminal provided on the base member and a terminal provided on the semiconductor device 910.

The device 9191 may include at least any one of an optical device 940, a control device 950, a processing device 960, a display device 970, a storage device 980, and a mechanical device 990. The optical device 940 corresponds to the semiconductor apparatus 930. The optical device 940 is, for example, a lens, a shutter, or a mirror, and includes an optical system that guides light to the semiconductor apparatus 930. The control device 950 controls the semiconductor apparatus 930. The control device 950 is, for example, a semiconductor apparatus such as an application specific integrated circuit (ASIC).

The processing device 960 processes a signal output from the semiconductor apparatus 930. The processing device 960 is a semiconductor apparatus such as a central processing unit (CPU) or an ASIC to be included in an analog front end (AFE) or a digital front end (DFE). The display device 970 is an electroluminescence (EL) display device or a liquid crystal display device that displays information (an image) acquired by the semiconductor apparatus 930. The storage device 980 is a magnetic device or a semiconductor device that stores information (an image) acquired by the semiconductor apparatus 930. The storage device 980 is a volatile memory such as a static random access memory (SRAM) or a dynamic RAM (DRAM), or a non-volatile memory such as a flash memory or a hard disk drive.

The mechanical device 990 includes a moving unit or a propulsion unit, such as a motor or an engine. The device 9191 displays a signal output from the semiconductor apparatus 930 on the display device 970 and transmits the signal to the outside using a communication device (not illustrated) included in the device 9191. Thus, in one embodiment, the device 9191 further includes the storage device 980 and the processing device 960 separately from a storage circuit and a calculation circuit included in the semiconductor apparatus 930. The mechanical device 990 may be controlled based on a signal output from the semiconductor apparatus 930.

The device 9191 is suitable for an electronic device such as an information terminal having an image capturing function (e.g., a smartphone and a wearable terminal) and a camera (e.g., an interchangeable lens camera, a compact camera, a video camera, and a monitoring camera). The mechanical device 990 in a camera can drive components in the optical device 940 for zooming, focusing, and shutter operation. Alternatively, the mechanical device 990 in a camera can move the semiconductor apparatus 930 for vibration-proof operation.

The device 9191 can be a transport device such as a vehicle, a ship, or a flight vehicle. The mechanical device 990 in the transport device can be used as a mobile apparatus. The device 9191 serving as the transport device is suitable for transporting the semiconductor apparatus 930 and for assisting and/or automating driving (operation) using the image capturing function. The processing device 960 for assisting and/or automating driving (operation) can perform processing for operating the mechanical device 990 serving as the mobile apparatus based on information acquired by the semiconductor apparatus 930. Alternatively, the device 9191 may be a medical device such as an endoscope, a measurement device such as a ranging sensor, an analytical device such as an electron microscope, an office device such as a copy machine, or an industrial device such as a robot.

According to the above-described exemplary embodiments, it is possible to acquire a good pixel characteristic. Accordingly, it is possible to increase the value of the semiconductor apparatus. Increasing the value includes at least any one of addition of functions, improvement of performance, improvement of characteristics, improvement of reliability, improvement of manufacturing yield, reduction of environmental burdens, cost reduction, miniaturization, and weight reduction.

Therefore, if the semiconductor apparatus 930 according to the present exemplary embodiment is used in the device 9191, the value of the device 9191 can also be improved. For example, if the semiconductor apparatus 930 is mounted on the transport device, excellent performance can be acquired in capturing an image of the outside of the transport device or measuring an external environment. Thus, making a decision in manufacturing and selling the transport device to mount the semiconductor device according to the present exemplary embodiment on the transport device is advantageous in improving the performance of the transport device itself. Particularly, the semiconductor apparatus 930 is suitable for the transport device that performs operation support and/or automatic operation of the transport device itself using information acquired by the semiconductor apparatus 930.

A photoelectric conversion system and a mobile body according to the present exemplary embodiment are described with reference to FIGS. 9B and 9C.

FIG. 9B illustrates an example of the photoelectric conversion system related to an on-vehicle camera. A photoelectric conversion system 8 includes a photoelectric conversion apparatus 80. The photoelectric conversion apparatus 80 is a photoelectric conversion apparatus (image capturing apparatus) described in any of the above-described exemplary embodiments. The photoelectric conversion system 8 includes an image processing unit 801 that performs image processing on a plurality of image data acquired by the photoelectric conversion apparatus 80 and a parallax acquisition unit 802 that calculates parallax (a phase difference of parallax images) from the plurality of pieces of image data acquired by the photoelectric conversion system 8. The photoelectric conversion system 8 includes a distance acquisition unit 803 that calculates a distance to a target object based on the calculated parallax, and a collision determination unit 804 that determines whether there is a possibility of collision based on the calculated distance. The parallax acquisition unit 802 and the distance acquisition unit 803 are examples of distance information acquisition units that acquire distance information to a target object. Specifically, the distance information is information regarding parallax, a defocus amount, a distance to the target object, and the like. The collision determination unit 804 may use any piece of the distance information to determine the possibility of collision. The distance information acquisition unit may be realized using specially designed hardware or a software module. The distance information acquisition unit may also be realized using a field programmable gate array (FPGA), an ASIC, or a combination thereof.

The photoelectric conversion system 8 is connected to a vehicle information acquisition apparatus 810 and can acquire vehicle information such as a vehicle speed, a yaw rate, and a steering angle. The photoelectric conversion system 8 is connected to a control engine control unit (ECU) 820, which is a control apparatus that outputs a control signal for generating a braking force to the vehicle based on a determination result by the collision determination unit 804. The photoelectric conversion system 8 is also connected to an alarm apparatus 830 that issues an alarm to a driver based on the determination result by the collision determination unit 804. For example, in a case where the collision determination unit 804 determines that there is a high possibility of collision, the control ECU 820 performs vehicle control to avoid the collision and reduce damage by applying a brake, releasing an accelerator, or suppressing an engine output. The alarm apparatus 830 issues an alarm to a user by sounding an alarm, displaying alarm information on a screen of a car navigation system or the like, or vibrating a seat belt or a steering wheel.

According to the present exemplary embodiment, the photoelectric conversion system 8 captures an image of surroundings of the vehicle, for example, front or rear of the vehicle.

FIG. 9C illustrates the photoelectric conversion system 8 in a case where an image of the front of the vehicle (an image capturing range 850) is captured. The vehicle information acquisition apparatus 810 transmits an instruction to the photoelectric conversion system 8 or the photoelectric conversion apparatus 80. With this configuration, accuracy of distance measurement can be further improved.

An example of controlling a vehicle to avoid collision with another vehicle is described above, but the present invention can also be applied to control to automatically drive a vehicle by following another vehicle, or control to automatically drive a vehicle to prevent it from running out of its lane. Further, the photoelectric conversion system can be applied to not only a vehicle such as an automobile but also, for example, a mobile body (mobile apparatus) such as a ship, an aircraft, or an industrial robot. In addition, the photoelectric conversion system can be applied to not only the mobile body but also a device that widely uses object recognition such as intelligent transport systems (ITS).

In the present specification, expressions such as “A or B”, “at least one of A and B”, “at least one of A and/or B”, and “one or more of A and/or B” can include all possible combinations of listed items, unless explicitly defined otherwise. Specifically, the above-described expressions are understood to describe all cases where at least one A is included, where at least one B is included, and where both at least one A and at least one B are included. This understanding is applied equally to combinations of three or more elements.

The described exemplary embodiments can be modified as appropriate without departing from the technical concept. The disclosure of the present specification includes not only what is explicitly described in the present specification, but also all matters that can be understood from the present specification and the drawings attached thereto. The disclosure of the present specification includes complement of the concepts described in the present specification. More specifically, if the present specification includes a description to the effect that, for example, “A is greater than B,” even if a description to the effect that “A is not greater than B” is omitted, it can be said that the present specification still describes that “A is not greater than B.” This is because the description that “A is greater than B” assumes a case where “A is not greater than B”.

According to the present invention, a decrease in sensitivity of a pixel can be suppressed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-021762, filed Feb. 16, 2024, which is hereby incorporated by reference herein in its entirety.

What is claimed is:

1. A photoelectric conversion apparatus in which a plurality of pixels is arranged in an array,
wherein each of the plurality of pixels includes:
a microlens;
a first photoelectric conversion element, a second photoelectric conversion element, a third photoelectric conversion element, and a fourth photoelectric conversion element that are provided on a substrate having a first surface and a second surface facing the first surface and are arranged in two rows and two columns to receive light via the microlens;
a first isolation portion provided between the first photoelectric conversion element and the second photoelectric conversion element;
a second isolation portion provided between the first photoelectric conversion element and the third photoelectric conversion element;
a third isolation portion provided between the third photoelectric conversion element and the fourth photoelectric conversion element; and
a fourth isolation portion provided between the second photoelectric conversion element and the fourth photoelectric conversion element,
wherein the first isolation portion, the third isolation portion, and a first opening provided between the first isolation portion and the third isolation portion are aligned in a first direction,
wherein the second isolation portion, the fourth isolation portion, and a second opening provided between the second isolation portion and the fourth isolation portion are aligned in a second direction,
wherein the first opening extends from the first surface to the second surface,
wherein the plurality of pixels includes a first pixel and a second pixel separated in the first direction, and the first pixel is closer to a center of an array formed of the plurality of pixels than the second pixel,
wherein arrangement of the first opening in the first pixel is different from arrangement of the first opening in the second pixel,
wherein each of the plurality of pixels is surrounded on four sides by an inter-pixel isolation portion, and
wherein each of the first isolation portion, the second isolation portion, the third isolation portion, and the fourth isolation portion is in contact with the inter-pixel isolation portion.

2. The photoelectric conversion apparatus according to claim 1, wherein each of the first isolation portion, the second isolation portion, the third isolation portion, and the fourth isolation portion is provided perpendicular to the inter-pixel isolation portion.

3. The photoelectric conversion apparatus according to claim 1, wherein a length of the first opening of the second pixel in the first direction is longer than a length of the first opening of the first pixel in the first direction.

4. The photoelectric conversion apparatus according to claim 3, wherein a length of the third isolation portion of the second pixel in the first direction is shorter than a length of the third isolation portion of the first pixel in the first direction.

5. The photoelectric conversion apparatus according to claim 4, wherein a length of the first isolation portion of the second pixel in the first direction is longer than a length of the first isolation portion of the first pixel in the first direction.

6. The photoelectric conversion apparatus according to claim 5, wherein an area of the third photoelectric conversion element of the second pixel is smaller than an area of the third photoelectric conversion element of the first pixel.

7. The photoelectric conversion apparatus according to claim 6, wherein an area of the first photoelectric conversion element of the second pixel is greater than an area of the first photoelectric conversion element of the first pixel.

8. The photoelectric conversion apparatus according to claim 3, wherein a length of the second opening of the second pixel in the second direction is shorter than a length of the second opening of the first pixel in the second direction.

9. The photoelectric conversion apparatus according to claim 3, wherein a length of the second opening of the second pixel in the second direction is equal to a length of the second opening of the first pixel in the second direction.

10. The photoelectric conversion apparatus according to claim 3, wherein a length of the second opening of the second pixel in the second direction is longer than a length of the second opening of the first pixel in the second direction.

11. The photoelectric conversion apparatus according to claim 1, wherein a length of the third isolation portion of the second pixel is shorter than a length of the third isolation portion of the first pixel.

12. The photoelectric conversion apparatus according to claim 1, wherein a distance between a center of the microlens of the second pixel and a center of the second pixel in the first direction is greater than a distance between a center of the microlens of the first pixel and a center of the first pixel in the first direction.

13. The photoelectric conversion apparatus according to claim 1,
wherein each of the plurality of pixels includes a color filter provided closer to a light incident surface, and
wherein a distance between a center of the color filter of the second pixel and a center of the second pixel in the first direction is greater than a distance between a center of the color filter of the first pixel and a center of the first pixel in the first direction.

14. The photoelectric conversion apparatus according to claim 1, wherein the second opening extends from the first surface to the second surface.

15. A photoelectric conversion system comprising:
the photoelectric conversion apparatus according to claim 1; and
a processing unit configured to generate an image using a signal output from the photoelectric conversion apparatus.

16. A photoelectric conversion system comprising:
the photoelectric conversion apparatus according to claim 1; and
a unit configured to acquire information about a distance to a target object based on a signal output from the photoelectric conversion apparatus.

17. A mobile body that includes the photoelectric conversion apparatus according to claim 1, the mobile body comprising:
a control unit configured to control a movement of the mobile body using a signal output from the photoelectric conversion apparatus.

18. A device comprising the photoelectric conversion apparatus according to claim 1, wherein the device further comprises at least any of:
an optical device configured to guide light to the photoelectric conversion apparatus;
a control device configured to control the photoelectric conversion apparatus;
a processing device configured to process a signal output from the photoelectric conversion apparatus;
a display device configured to display information acquired by the photoelectric conversion apparatus;
a storage device configured to store information acquired by the photoelectric conversion apparatus; and
a mechanical device configured to operate based on information acquired by the photoelectric conversion apparatus.
